(19) United States
(12) Patent Application Publication
(10) Pub. No.: US 2016/0217982 A1
(43) Pub. Date: Jul. 28, 2016

(54) METHOD AND DEVICE FOR DETECTING A PLASMA IGNITION

(71) Applicants: CENTROTHERM PHOTOVOLTAICS AG, Blaubeuren (DE); HQ-DIELECTRICS GMBH, Dornstadt (DE)

(72) Inventors: Wilhelm Kegel, Laichingen (DE); Wilfried Lerch, Dornstadt (DE); Jürgen Niess, Sontheim (DE); Nicole Sacher, Dornstadt (DE)

(21) Appl. No.: 14/913,419

(22) PCT Filed: Aug. 22, 2014
(86) PCT No.: PCT/EP2014/067897

§ 371 Date: Feb. 22, 2016

(30) Foreign Application Priority Data
Aug. 23, 2013 (DE) 10 2013 014 147.8

(51) Int. Cl. H01J 37/32; G01L 23/08

(52) U.S. Cl. CPC H01J 37/32917; G01L 23/08

(57) ABSTRACT

Disclosed are a method and an apparatus for the detection of a plasma in a process chamber for the treatment of substrates. In the method, the pressure within the chamber is measured over a period of time using a pressure sensor, a sudden change in pressure is detected and an ignition or extinguishing of a plasma determined at least by means of the pressure change. The apparatus comprises a process chamber, for receiving at least one substrate, with at least one plasma generator, at least one pressure sensor which is situated so as to detect the pressure within the process chamber and output an output signal corresponding to the pressure, and at least one evaluation unit. The evaluation unit is capable of monitoring over a period of time an output signal from the pressure sensor and, on the basis of at least one sudden change in the output signal of the pressure sensor, of determining an ignition and/or an extinguishing of a plasma.

### RELATED APPLICATIONS

This application corresponds to PCT/EP2014/0067897, filed Aug. 22, 2014, which claims the benefit of German Application No. 10 2013 014 147.8, filed Aug. 23, 2013, the subject matter, of which are incorporated herein by reference in their entirety.

### SUMMARY OF THE INVENTION

The present invention relates to a method and an apparatus for the detection of a plasma and especially a plasma ignition and/or an extinguishing of a plasma in a process chamber for the treatment of substrates, especially semiconductor substrates.

In the manufacture of electronic components, such as memory chips, microprocessors, but also in photovoltaic or in the field of flatscreens, different production steps are necessary for the manufacture of an end product in the process of manufacturing these products, different layers are applied in the construction of the electronic components. An important category of such layers are dielectric layers which insulate different layers. As in the case of all other layer structures it is necessary to apply the dielectric layer accurately and reliably in order to guarantee the functionality of the component.

For the formation of dielectric or other layers or for the treatment of such layers on a substrate, different methods are known. In particular, many thermic treatment processes are known. A more recent development has shown that the use of a plasma in the layer formation on substrates or in the treatment of substrates can be advantageous.

In WO 2010/015385, a rod-shaped microwave-plasma electrode is described in which an inner conductor in a first partial region is completely surrounded by an outer conductor. Adjacent to this partial region is a further partial region in which the outer conductor provides an opening which broadens towards a free end. In the region of the broadened opening, microwave power is decoupled for the production of a plasma. Such rod-shaped plasma electrodes can be situated lying opposite to the substrate requiring treatment and the substrate is not situated between the electrodes which produce the plasma, such as was the case in older treatment apparatuses, such as is the case, for example, in the apparatus according to US 2005 01 64 523 A1. With such plasma electrodes it is possible to achieve improved processing results.

An example of an application of such plasma electrodes involves the formation of dielectric layers on semiconductor substrates, such as is described, for example, in DE 10 2011 100 024 A1. Here, a process gas is fed into contact with the semiconductor substrate and a plasma is produced from the process gas which is adjacent to at least one surface of the semiconductor substrate.

In all treatment processes which utilise plasma it is important for the process that it is known when a plasma burns (i.e. when it has ignited) and when not (i.e. where appropriate when it has been extinguished). This is especially important in processes in which only a weak microwave power is fed into the microwave electrode(s) and a plasma ignition does not always take place or only happens after a delay. Until now there has been no known reliable method for measuring this.

It would be possible for optical sensors to suddenly detect a light source emitted by the plasma but only when there are no further light sources present which could superimpose on the plasma light source, such as for example could foe the case with the heating lamps within the process chamber.

For this reason it is an object of the present invention to provide a method and apparatus for the detection of a plasma which allow the reliable detection of a plasma.

In accordance with the invention a method is provided according to Claim 1 and an apparatus in Claim 4 which allow to detect a plasma. Further embodiments of the invention result from the sub-claims.

In particular, in the method for the detection of a plasma in a process chamber for the treatment of substrates, the pressure within the process chamber is measured with a pressure sensor over a period of time, a sudden change in pressure is detected and an ignition or extinguishing of a plasma is determined on the basis of at least the pressure change. The method hereby allows a simple method for the reliable detection of a plasma in the process chamber in which use can be made of a pressure sensor which is usually present in the chamber.

Preferably, the plasma is generated by means of a plurality of rod-shaped microwave electrodes possessing inner conductors and outer conductors, in which case it is determined by means of the amplitude of the pressure change whether a plasma has ignited or been extinguished in the region of all or only of individual microwave electrodes. With amplitude recognition a more precise statement can be made with regard to the ignition and/or extinguishing of a plasma. This method is particularly suitable for use with microwaves at approximately 2.45 GHz because of the high dissociation of gases, which can be higher by a factor of approximately 10⁴ than in other plasma processes, such as e.g. RF plasma generation at 13.58 MHz.

In an embodiment of the invention at least one of the additional process parameters is taken into consideration in the determining of an ignition and/or an extinguishing of a plasma: the process gas composition, control parameter of a vacuum unit and/or a gas feed, the temperature in the process chamber, the microwave power which is fed into at least one microwave electrode and/or thereby reflected, and the number of microwave electrodes. These enable, in addition to the simple detection of an ignition and/or an extinguishing of a plasma, an additional analysis with regard to the possible reasons for the ignition and/or the extinguishing and/or for an ignition which does not take place (despite being expected). These can be taken into consideration where appropriate in the current procedure or in a future procedure. They can also facilitate a plausibility check in the reporting of an ignition or extinguishing of the plasma.

The apparatus for the detection of a plasma in a process chamber for the treatment of substrates shows a process chamber for the mounting of at least one substrate with at least one plasma generator, at least one pressure sensor which is so positioned as to detect the pressure within the process chamber and output an output signal corresponding to the pressure, and at least one evaluation unit. The evaluation unit is capable of monitoring an output signal from the pressure sensor over a period of time and, as a result of at least one sudden change in the output signal of the pressure sensor, determining an ignition or an extinguishing of a plasma. Such an apparatus facilitates a reliable and simple detection of a plasma in a process chamber using means usually present in the process chamber.

Preferably the at least one plasma generator comprises at least one microwave electrode which is so positioned as to feed microwave radiation into the process chamber. The apparatus preferably comprises means for the determining of values of at least one of the following process parameters: the process gas composition, control parameters of a vacuum unit and/or a gas feed, the temperature in the process chamber, the microwave power which is fed into at least one microwave electrode and/or thereby reflected, and, as appropriate, the number of microwave electrodes, and wherein the at least one evaluation unit is additionally capable of monitoring over a period of time a signal which corresponds with at least one of the above-mentioned values, and of taking the signal into account in the determination of an ignition and/or an extinguishing of a plasma. Thereby a more precise detection of a plasma is facilitated, and also, where appropriate, an analysis of a defective ignition, non-ignition or extinguishing of a plasma.

Preferably, the apparatus comprises at least one microwave electrode, having inner conductors and outer conductors, which is supplied on one side with microwaves, in which the outer conductor forms an opening for coupling-out which broadens, culminating in a free end of the electrode.

For a reliable detection and for the protection of the pressure sensor, the pressure sensor is preferably situated outside an expected plasma region of the at least one microwave electrode.

### BRIEF DESCRIPTION OF THE DRAWINGS

The invention will now be described more closely with the use of figures; in the drawings:

FIG. 1 shows a schematic sectional view through an apparatus for the treatment of substrates with the use of a plasma;

FIG. 2 shows a graph which shows an example of en output signal of the pressure sensor during a first example of a plasma treatment;

FIG. 3 shows a graph which shows an example of an output signal of the pressure sensor during a second example of a plasma treatment.

### DESCRIPTION

The relative terms used in the following description, such as “left”, “right”, “above” and “below” refer to the drawings end should not restrict the application in any way, even if they describe preferred layouts.

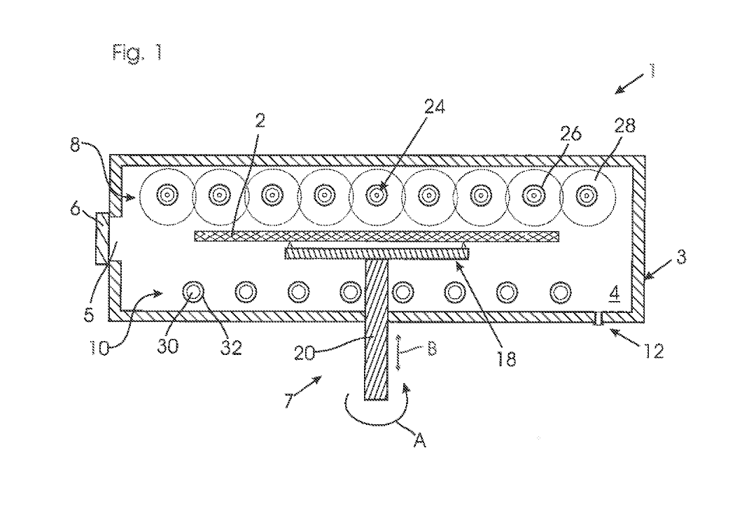

FIG. 1 shows a schematic sectional view of an apparatus 1 for the treatment of substrates 2 with the help of a plasma. The apparatus 1 has a casing 3 which is in the form of a vacuum casing. Within the casing 3 a process chamber 4 is defined. The casing 3 has a loading and unloading opening 5 which can be opened and shot in the usual manner by means of a door mechanism 6. The process chamber 4 can be reduced by means of a vacuum unit (not shown) to a negative pressure, and can be supplied with a process gas by means of a suitable gas feed (also not shown). Through the gas feed, different process gases—as required—can be fed into the process chamber in the usual way in the desired combinations and in controlled quantities.

The apparatus 1 also has a substrate carrier-unit 7, a plasma unit 8, a heating unit 10 and a detection unit 12. The carrier unit 7 has a substrate receptacle 18 which is carried via a shaft 20 which is rotatable within the process chamber 4, as is shown by arrow A. The shaft 20 is connected for this reason to a rotating unit which is not further illustrated. In addition, the shaft 20 and the receptacle 18 can be moved up and down, as shown by the two-headed arrow B. Hereby the receiving plane of receptacle 18 can be moved up or down within the process chamber, as will be described hereafter in even closer detail.

The plasma unit 8 is composed of a plurality of rod-shaped plasma electrodes 24 of the microwave sort, as is described in WO 2010/015386 A, which is quoted with regard to the construction of the microwave electrode in order to avoid repetition. In particular, the plasma electrodes 24 are microwave electrodes, having inner conductors and outer conductors, supplied on one side with microwaves. The outer conductor is formed in such a way that it forms an opening for coupling-out microwaves which broadens to a tree end of the microwave electrode. Hereby a uniform coupling-out of microwaves and a uniform plasma can be achieved over the length of the microwave electrode. For the coupling-in of microwaves into the microwave electrode, a microwave generator (not shown) is provided. In addition means can be provided which can determine the coupled-in and/or the reflected microwave power for each microwave electrode.

The plasma electrodes 24 are housed in cladding tubes 26 made of dielectric material, such as quartz, and are in this way isolated from the processing atmosphere within the process chamber 4. These cladding tubes 26 can extend through the entire process chamber 4 and lead (appropriately sealed) to the outside through suitable openings in the housing 3, such as is described in e.g. DE 20 2010 050 258 A, to which reference is made in this regard and also by reason of a multi-part chamber construction, in order to avoid repetition. The cladding tubes 26 can also, however, be disposed in a different manner in order to house the plasma electrodes 24, or the plasma electrodes 24 could also all together be isolated from the process chamber 4 by means of a single plate element in the illustrated arrangement a plasma 28 can be formed from the utilised process gas around the respective plasma electrodes 24, inasmuch as the microwave power coupled-into the plasma electrodes 24 is sufficient to ignite the plasma. This depends also on (among other things) additional process conditions, such as e.g. the pressure and the composition of the process gas, as the skilled person will recognise. The individual plasmas 28 essentially merge in the course of the process to a single plasma.

The heating unit 10 is composed of a plurality of radiation sources 30 which can be positioned parallel with or perpendicularly to the plasma electrodes 24. The radiation sources each comprise a lamp, such as an arc lamp or a halogen lamp, which is housed in a cladding tube 32 which is made of e.g. quartz. Also in this case the radiation sources 30 could be isolated from the process chamber by means of a shared quartz plate. The radiation of the radiation sources 30 is capable of warming the substrate 2 directly, when the receptacle 18 is transparent for the main part of the radiation of the radiation source 30. To this end the receptacle 18 could be made e.g. from quartz. It is however also possible to provide an indirect heating for the substrate 2, to which end the receptacle 18 could be made of a material which absorbs the main part of the radiation from the radiation source 30. The radiation would then warm the receptacle 18 which then in turn warms the substrate 2.

The apparatus 1 has preferably at least one temperature measuring unit in order to determine the temperature of substrate 2. The determined temperature reading can be transferred to a control unit (not shown) which can control the heating unit 10 on the basis of the temperature reading, in order to maintain a pre-determined temperature of the substrate, as is usual in this technological area.

The detection unit 12 has a pressure gauge well-known in semiconductor technology which is capable of measuring the pressure in the process chamber 4 and outputting a corresponding signal. The detector unit 12 extends through the base of the housing 3 and is connected with the process chamber 4. Pressure sensors of this sort are usually used for pressure measurement in a process chamber, in order to facilitate a regulation of the pressure via a corresponding activation of the vacuum unit and/or the gas feed. To this end the measurement results of the detector unit are transferred to a corresponding regulating unit which has e.g. a processor unit in which corresponding regulation algorithms can be carried out. In the present embodiment the detector unit 12 has the (additional) purpose of detecting the presence of a plasma 28 by detecting the ignition or the extinguishing of a plasma 28. To this end an evaluation unit is provided which is capable of tracking an output signal, correlating to the pressure in the process chamber 4, detected by the detector unit 12 over a period of time and, in the case of a sudden change in the output signal of the pressure sensor, to ascertain the ignition or extinguishing of a plasma. In this ascertainment further parameters can be utilised, which primarily facilitate a plausibility check, as will be discussed in more detail hereafter.

The operation of apparatus 1 will now he discussed in more detail with reference to the drawings, it is assumed that the substrate 2 is a silicon semiconductor wafer, upon which a silicon oxide layer is formed as a dielectric layer. During operation, however, further layers can be formed, or a layer treatment without a layer formation or even an etching procedure can be carried out.

To this end, a suitable process gas, for example pure oxygen or an oxygen-hydrogen mixture or in a mixture with N₂ or NH₃ is fed into the process chamber 4 in which there is negative pressure. Subsequently the plasma electrodes 24 are supplied with microwaves and feed the latter (apart from a part which is reflected) into the process chamber 4. The microwaves effect, when an appropriate procedure is carried out, the ignition of a plasma 23 of the process gas. The substrate may also be optionally brought up to a desired process temperature by means of the heating unit 10.

The process gas causes layer growth on the surface of the substrate, which is influenced by the plasma. While the plasma 28 burns, the distance between the plasma electrodes 24 (and consequently the plasma 28) and the surface of the substrate 2 can be altered. In this way, different growth mechanisms for the layer growth can be configured. These are affected by different interactions between the plasma and the substrate. In particular, when the distances are smaller, a clear excess of electrons in relation to ions and radicals adjacent to the surface of the substrate can be configured. This results in an anodic oxidation of the substrate surface, depending on the process gases. Such an anodic oxidation is self-adjusting, since a larger electrical field results where lesser layer thicknesses are formed. This accelerates in its turn the layer growth locally. The term “anodic” is here used to denote that the reactions of oxidation, nitridation etc. are primarily driven by electrons/ions or by means of the resulting electrical field. When the distance to the surface of the substrate is greater, there are generally only radicals to be found adjacent to the surface of the substrate. Because of this the result is a radical oxidation of the surface of the substrate, dependent on the process gas. “Radical” is used here to describe a reaction which is primarily driven by the radicals created in the plasma.

By means of a suitable gas input different gas combinations and/or different gas pressures can be configured in the region of the respective plasmas 28 underneath the plasma electrodes 24, which, as a rule, overlap one another and mix to form an overall plasma. The plasma can also be operated in a pulsed manner during the process.

For the above-described process sequence it is important that the plasma also ignites reliably, which can be problematic, especially when the fed-in microwave energy is supposed to be low. For this reason, according to the present invention, the presence of a plasma should be reliably and definitely detected. This is carried out by the detector unit 12, which detects the pressure in the process chamber 4 and emits a corresponding signal (e.g. in the form of a voltage) in combination with the evaluation unit described above.

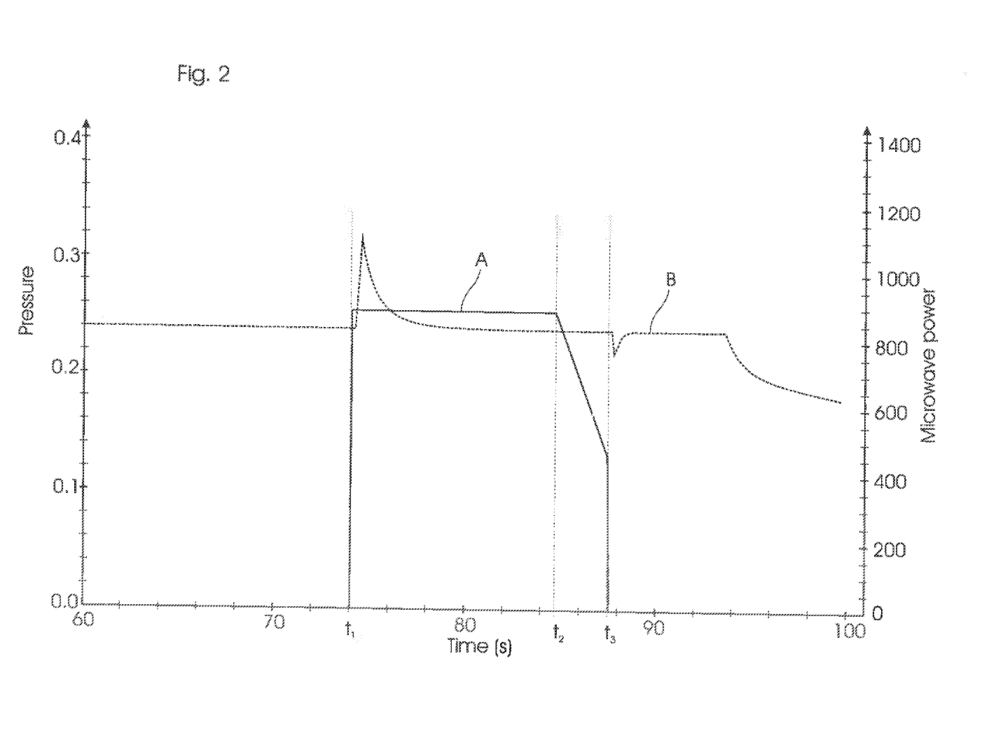

As will be described more closely hereafter with reference to FIG. 2, sudden pressure changes in the process chamber result both from the ignition of a plasma and from its extinguishing. FIG. 2 shows an exemplary graph of a power applied to the plasma electrodes 24 (Graph A) and an exemplary graph of the pressure within the process chamber (Graph B) during a low-temperature oxidation of a silicon wafer in a system of the type described above. The x-axis shows the time in seconds, the right-hand y-axis shows the microwave power applied and the left-hand y-axis shows the pressure measured.

In the above example, pure oxygen was used as a process gas and a pressure of 240 mTorr was selected as a process pressure. This was first preset by an appropriate activation of the vacuum unit and/or the gas feed, as is usually carried out, and the pressure unit 12 provided a signal corresponding to the pressure for the controller. At time t₁ the plasma electrodes 24 were supplied with microwave power which was held substantially constant until time t₂ and then substantially continually reduced until time t₃ when it was turned off altogether.

It can be seen that the pressure prior to time t₁ was substantially constant and then at time t₁ or shortly after shows a sudden increase, which is quickly brought back to process-pressure by means of the above-mentioned regulation. This sudden increase in pressure is caused by the ignition of a plasma and the dissociation of gas related to the ignition. By means of the above-mentioned regulation this pressure increase is quickly brought back to process-pressure. At time is the pressure then suddenly decreases, which is related to the extinguishing of the plasma and the recombination of plasma particles. Although the process is here ended by the switching off of the microwave power (and the extinguishing of the plasma), the regulator brings the pressure at first back to the process pressure. This is however not necessary for normal operation. In the case of an unplanned extinguishing of the plasma this would of course take place, and a peak would show as in the ease of the ignition, albeit with a negative value. By means of the continual decrease of the microwave power and a corresponding reduction of the plasma expansion, the corresponding peak at the extinguishing of the plasma is smaller than that shown at the ignition of the plasma, if the microwave power were to be abruptly cut off, as could occur in a malfunction, the corresponding peak would be of an accordingly greater amplitude.

The change in pressure (output signal of the detector unit 12) at the time of the ignition of the plasma can be recorded in an evaluation unit (not shown). This evaluates the signal over a period of time and, on the basis of a sudden change, recognises the presence of a plasma (period between sudden rise and sudden decrease). If an unscheduled extinguishing of the plasma takes place (despite supplying the plasma electrodes 24 with microwaves), this is displayed and detected by means of an accordingly sudden decrease.

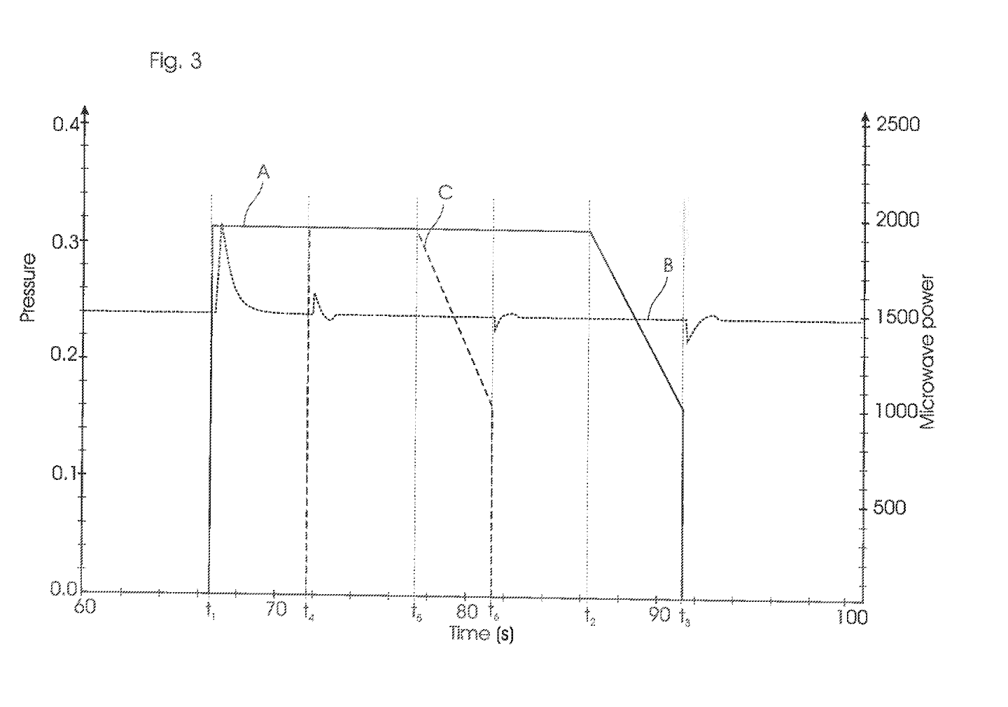

FIG. 3 displays corresponding graphs for an alternative process sequence. Here, graph A shows a power which is applied to only 4 of the plasma electrodes (corresponding to a partial ignition of the plasma), graph B shows the pressure within the process chamber and graph C shows the power applied to an additional fifth plasma electrode (corresponding to a delayed partial ignition of the plasma in the region of this plasma electrode).

Again, pure oxygen was used as the process gas and a pressure of 240 mTorr was selected as process pressure. At time t₁ the four plasma electrodes 24 (in the example, the four outer electrodes) were supplied with microwave power, which was held substantially constant until time t₂ and then substantially continually reduced until time t₃ when it was turned off altogether. At time t₄ the middle plasma electrodes 24 were supplied with microwave power, which was held substantially constant until time t₆ and then substantially continually reduced until time t₇ when it was turned off altogether.

Again, the pressure before time t₁ is substantially constant and at time t₁ or shortly after shows a sudden increase, which is quickly brought back to process-pressure by means of the above-mentioned regulator. At time t₄ or shortly after there takes place a further sudden increase in pressure which is also quickly brought back to process pressure. The second sudden increase in pressure has a smaller amplitude than the first. The reason for this is that, in contrast to the first (outer) plasmas, only a small (middle) plasma has ignited. Both pressure peaks are caused by the ignition of a plasma and the dissociation of gas related to the ignition. At time t₆ there is a sudden pressure drop in the chamber which is connected with the extinguishing of the middle plasma and a corresponding recombination of plasma particles in this region. At time t₃ the pressure drops again suddenly, which is connected with the extinguishing of the rest of the plasma. This second exemplary process sequence shows that even partial ignitions and/or partial extinguishings of a plasma can be detected on the basis of pressure changes.

As the skilled person will recognise, the amplitude of the change is dependent on different parameters, such as the output pressure before the change (process pressure), the process gas composition (more complex gas molecules create greater amplitudes in dissociation) and, where appropriate, the temperature. The microwave power which was fed in can also influence the amplitude of the pressure change, since it can influence the expansion of the plasma. By considering the amplitude in the knowledge of at least one of these parameters it can be ascertained whether a plasma in the region of all plasma electrodes 24 has ignited or been extinguished; since the number of plasma electrodes 24, in the region of which a plasma has ignited or been extinguished, also influences the amplitude. This is why in the detection of a plasma the following parameters can be taken into account in addition to the pressure data: process gas composition, the temperature in the process chamber, the microwave power fed into at least one microwave electrode and/or thereby reflected, and the number of the supplied microwave electrodes.

Although all parameters together facilitate an improved statement, it is also possible to use only one of these parameters. Control parameters of the vacuum unit and/or the gas feed can also be used as additional parameters in the detection of a plasma, since these too can cause sudden changes which should preferably be differentiated from the changes resulting from the ignition or extinguishing of a plasma. By means of one or more of the above-mentioned parameters it is possible to carry out a plausibility check. For example, a sudden increase in pressure can obviously not be the result of a plasma ignition if no microwave power is being fed into the plasma electrodes 24, it can also be assumed that by the point at which the plasma electrodes 24 are switched off, at the very latest, the plasma will be extinguished, even if no sudden pressure loss is detected. In the case of such “mis-detections”, an automatic or manual error search can be initiated, where appropriate, and/or an alert can be sent to an operator. Where appropriate the current process can be aborted or the implementation of further processes can be stopped.

When further parameters are detected they can provide clues as to the reasons for an unscheduled plasma ignition (or non-ignition) and/or the unscheduled extinguishing of a plasma which can be taken into account in the current process or in a later process.

The process described above was described with the formation of an oxide layer as a dielectric layer, but it can also, as already mentioned, be used for other processes using other process gases. In particular, it is possible to form other layers. It can also be used for the treatment of layers and/or for the removal of layers and/or contaminants. In any case, the detection of a plasma during the process is important, since this can affect the process significantly.

The invention has until now been described by means of preferred embodiments of the invention, without being limited to the concrete embodiments. In particular, a different construction can be provided for the detector unit 12, as long as the detector unit is capable of detecting the pressure in the process chamber 4 and emitting a signal correlating to the pressure. Although the process is preferably to be used in combination with a microwave plasma, it can also be used in combination with other plasma generation methods, such as in combination with a RF plasma.

1. A method for the detection of a plasma in a process chamber for the treatment of substrates which comprises the following steps:
measuring the pressure within the process chamber with a pressure sensor over a period of time;
detecting a sudden pressure change; and
determining an ignition or an extinguishing of a plasma at least based on the pressure change.

2. Method according to claim 1, in which the plasma is generated by means of a plurality of rod-shaped microwave electrodes having inner conductors and outer conductors, and in which if is determined at least by the amplitude of the pressure change whether a plasma has ignited or been extinguished in the region of all microwave electrodes or only isolated microwave electrodes.

3. Method according to claim 1, in which at least one of the following parameters is taken into consideration when determining the ignition and/or extinguishing of the plasma: the process gas composition, control parameters of a vacuum unit and/or a gas feed, the temperature in the process chamber, the microwave power which is fed into at least one microwave electrode and/or thereby reflected, and the number of microwave electrodes.

4. Apparatus for the detection of a plasma in a process chamber for the treatment of substrates which comprises the following:
a process chamber for receiving at least one substrate, having at least one plasma generator;
at least one pressure sensor which is so situated that it can detect the pressure within the process chamber and output an output signal corresponding to the pressure; and
at least one evaluation unit which is capable of monitoring an output signal from the pressure sensor over a period of time and, as a result of at least one sudden change in the output signal of the pressure sensor, determining an ignition or an extinguishing of a plasma.

5. Apparatus according to claim 4, in which the plasma generator comprises at least one microwave electrode which is so positioned as to feed microwave radiation into the process chamber.

6. Apparatus according to claim 4, in which the apparatus also comprises means for determining the values of at least one of the following parameters: the process gas composition, control parameter of a vacuum unit and/or a gas feed, the temperature in the process chamber, the microwave power which is fed into at least one microwave electrode and/or thereby reflected, and as appropriate the number of microwave electrodes, and where the at least one evaluation unit is additionally capable of monitoring over a period of time a signal which corresponds with at least one of the above-mentioned values, and of taking the signal into account in the determination of an ignition and/or an extinguishing of a plasma.

7. Apparatus according to claim 4, in which the plasma is generated by a rod-shaped microwave electrode with an inner conductor and an outer conductor which is supplied on one side with microwaves, and in which the outer conductor forms an opening for coupling-out microwaves which broadens towards a free end of the electrode.

8. Apparatus according to claim 4, in which the pressure sensor is situated outside an expected plasma region of the at least one microwave electrode.

9. A data medium upon which instructions are saved which can be carried out by a computer, which instructions, when they are carried out by a computer, initiate the carrying out of a method according to claim 3.
